(19) United States
(12) Patent Application Publication
(10) Pub. No.: US 2014/0374307 A1
(43) Pub. Date: Dec. 25, 2014

(54) SYSTEM AND METHOD FOR CONTROLLING TRANSPORTATION OF SUBSTRATE OF LIQUID CRYSTAL PANEL

(71) Applicants: Minghu Qi, Shenzhen (CN); Chun-hao Wu, Shenzhen (CN); Kun-hsien Lin, Shenzhen (CN); Yongqiang Wang, Shenzhen (CN); Zhenghong Chen, Shenzhen (CN); Weibing Yang, Shenzhen (CN); Erqing Zhu, Shenzhen (CN); Zhenhua Guo, Shenzhen (CN)

(72) Inventors: Minghu Qi, Shenzhen (CN); Chun-hao Wu, Shenzhen (CN); Kun-hsien Lin, Shenzhen (CN); Yongqiang Wang, Shenzhen (CN); Zhenghong Chen, Shenzhen (CN); Weibing Yang, Shenzhen (CN); Erqing Zhu, Shenzhen (CN); Zhenhua Guo, Shenzhen (CN)

(73) Assignee: Shenzhen China Star Optoelectronics Technology Co. Ltd., Shenzhen (CN)

(21) Appl. No.: 13/502,746

(22) PCT Filed: Mar. 15, 2012
(86) PCT No.: PCT/CN12/72388

§ 371 Date: Apr. 19, 2012

(30) Foreign Application Priority Data
Mar. 14, 2012 (CN) 201210066801.9

(51) Int. Cl. H01L 21/673; B65G 49/00

(52) U.S. Cl. CPC H01L 21/67396; H01L 21/67353; H01L 21/67393; B65G 49/00
USPC 206/719; 206/710; 414/806

(57) ABSTRACT

A system and method for controlling transportation of a substrate of a liquid crystal panel is disclosed. Said method comprises: putting the substrate of the liquid crystal panel into a transport apparatus; humidifying the transport apparatus having the substrate of the liquid crystal panel placed thereinto by utilizing a humidifying apparatus to form a mist in the transport apparatus; and transporting the substrate of the liquid crystal panel by utilizing the humidified transport apparatus. The present invention prevents the substrate of the liquid crystal panel from being damaged by electrostatic charges and ensures product percent of pass.

### TECHNICAL FIELD OF THE INVENTION

The present invention relates to liquid crystal panel manufacture, and more particularly, to a system and method for controlling transportation of a substrate of a liquid crystal panel.

### BACKGROUND OF THE INVENTION

As a liquid crystal panel is continuously developed and widely used, highly demanding standards are required for liquid crystal panel manufacture.

In a process of transporting a substrate of the liquid crystal panel, taking a piece of thin-film-transistor (TFT) glass as the aforesaid substrate for example, the TFT glass is transported mostly by using a cassette during the TFT glass transporting process. The cassette transportation is classified into the following two ways.

The first is a random cassette transportation. The advantage of this way is that it provides flexibility to select the TFT glasses as desired for the transportation; the disadvantage of this way is that the capacity of the cassette to transport the TFT glasses is small, and thereby resulting in low production efficiency.

The second is a sequential cassette transportation. The advantage of this way is that the number of transported TFT glasses is much larger and the production efficiency is high; the disadvantage of this way is that it is not able to quickly select the required TFT glasses.

Since the efficiency of the sequential cassette transportation is much higher, most of conventional skills adopts this way to transport the substrate of the liquid crystal panel. Referring to FIGS. 1a to 1c, FIGS. 1a to 1c are schematic diagrams showing a cassette utilized for transporting the substrate of the liquid crystal panel by the sequential cassette transportation, in which FIG. 1a is a front view, FIG. 1b is a side view, and. FIG. 1c is a bottom view. FIG. 1d is a side view of FIG. 1c.

Referring to FIG. 1a and FIG. 1b, the cassette 10 comprises a left column 11 and a right column 12. The cassette 10 also has a slot 13 disposed therein. Referring to FIG. 1c and FIG. 1d, the cassette 10 has a wheel or a roller 14 disposed at the bottom thereof. The substrate of the liquid crystal panel is further supported by a supporting rope 15.

Referring to FIG. 1a and FIG. 1c, the substrate of the liquid crystal panel is placed at an entrance of the slot 13 when putting the substrate of the liquid crystal panel into the cassette 10 during the process of transporting the substrate of the liquid crystal panel. The substrate (e.g., a TFT glass) of the liquid crystal panel is inserted into the slot 13 with the help of sliding motion of the wheel 14. Referring to FIG. 1b, the substrate of the liquid crystal panel is put into and pulled out from the cassette 10 along the direction A.

If it needs to pull out the substrate of the liquid crystal panel, the substrate of the liquid crystal panel has to be removed from the slot 13 with the help of the sliding motion of the wheel 14.

It is obvious that electrostatic charges may generate since the substrate of the liquid crystal panel rubs with the wheel 14 and the slot 13 of the cassette 10 in the process of transporting the substrate of the liquid crystal panel. Once the generated electrostatic charges are accumulated to a certain level, it will damage the substrate (e.g., the TFT glass) of the liquid crystal panel and thereby reducing product percent of pass and wasting the resources.

### SUMMARY OF THE INVENTION

An objective of the present invention is to provide a method for controlling transportation of a substrate of a liquid crystal panel for solving a problem occurred in a process of transporting the substrate of the liquid crystal panel in conventional skills. The problem is that the substrate of the liquid crystal panel may be damaged by electrostatic charges caused by rubbing between materials.

To solve the above problem, the present invention provides a method for controlling transportation of a substrate of a liquid crystal panel, said method comprising steps of providing a transport apparatus and a humidifying apparatus; putting the substrate of the liquid crystal panel into the transport apparatus; spraying atomized pure water into the transport apparatus by utilizing the humidifying apparatus to form a mist in the transport apparatus, and meanwhile controlling a spray amount of the humidifying apparatus to make relative humidity in the transport apparatus greater than 65%, wherein particles of the atomized pure water range from one to five micrometers in diameter; and transporting the substrate of the liquid crystal panel by utilizing the humidified transport apparatus.

In the method for controlling transportation of the substrate of the liquid crystal panel according to the present invention, the humidifying apparatus is a mist generator.

In the method for controlling transportation of the substrate of the liquid crystal panel according to the present invention, when forming the mist in the transport apparatus by spraying the atomized pure water into the transport apparatus by utilizing the humidifying apparatus, the humidifying apparatus is controlled to spray toward a region where the substrate of the liquid crystal panel is in contact with the transport apparatus.

Another objective of the present invention is to provide a method for controlling transportation of a substrate of a liquid crystal panel for solving a problem occurred in a process of transporting the substrate of the liquid crystal panel in conventional skills. The problem is that the substrate of the liquid crystal panel may be damaged by electrostatic charges caused by rubbing between materials.

To solve the above problem, the present invention provides a method for controlling transportation of a substrate of a liquid crystal panel, said method comprising steps of: providing a transport apparatus and a humidifying apparatus; putting the substrate of the liquid crystal panel into the transport apparatus; humidifying the transport apparatus having the substrate of the liquid crystal panel placed thereinto by utilizing the humidifying apparatus to form a mist in the transport apparatus; and transporting the substrate of the liquid crystal panel by utilizing the humidified transport apparatus.

In the method for controlling transportation of the substrate of the liquid crystal panel according to the present invention, the humidifying apparatus is a mist generator.

In the method for controlling transportation of the substrate of the liquid crystal panel according to the present invention, the step of humidifying the transport apparatus having the substrate of the liquid crystal panel placed thereinto by utilizing the humidifying apparatus to form the mist in the transport apparatus comprises: spraying atomized pure water into the transport apparatus by utilizing the humidifying apparatus; wherein particles of the atomized pure water range from one to five micrometers in diameter.

In the method for controlling transportation of the substrate of the liquid crystal panel according to the present invention, when forming the mist in the transport apparatus by spraying the atomized pure water into the transport apparatus by utilizing the humidifying apparatus, the humidifying apparatus is controlled to spray toward a region where the substrate of the liquid crystal panel is in contact with the transport apparatus.

In the method for controlling transportation of the substrate of the liquid crystal panel according to the present invention, when forming the mist in the transport apparatus by spraying the atomized pure water into the transport apparatus by utilizing the humidifying apparatus, a spray amount of the humidifying apparatus is controlled so as to make relative humidity in the transport apparatus greater than 65%.

Another objective of the present invention is to provide a system for controlling transportation of a substrate of a liquid crystal panel for solving a problem occurred in a process of transporting the substrate of the liquid crystal panel in conventional skills. The problem is that the substrate of the liquid crystal panel may be damaged by electrostatic charges caused by rubbing between materials.

To solve the above problem, the present invention provides a system provided for controlling transportation of a substrate of a liquid crystal panel, said system comprising a transport apparatus and a humidifying apparatus; wherein said transport apparatus is utilized to accommodate the substrate of the liquid crystal panel as well as transport the substrate of the liquid crystal panel; wherein said humidifying apparatus is disposed at at least one side of the transport apparatus, and said humidifying apparatus is utilized to humidify the transport apparatus to form a mist in the transport apparatus.

In the system for controlling transportation of the substrate of the liquid crystal panel according to the present invention, the humidifying apparatus is a mist generator.

In the system for controlling transportation of the substrate of the liquid crystal panel according to the present invention, the mist formed in the transport apparatus is atomized pure water, and wherein particles of the atomized pure water range from one to five micrometers in diameter.

In the system for controlling transportation of the substrate of the liquid crystal panel according to the present invention, the humidifying apparatus is also utilized to be controlled to spray toward a region where the substrate of the liquid crystal panel is in contact with the transport apparatus.

In the system for controlling transportation of the substrate of the liquid crystal panel according to the present invention, relative humidity in the transport apparatus is greater than 65% after spraying by utilizing the humidifying apparatus.

As compared to the conventional skills, the present invention is to humidify the transport apparatus by utilizing the humidifying apparatus to form a mist in the transport apparatus. The mist will form a water film on the surfaces of the transport apparatus and the substrates of the liquid crystal panel. The water film is a layer that is extremely thin. The water film can dissolve carbon dioxide (CO2) in air such that the resistance measured on the surfaces of the transport apparatus and the substrate of the liquid crystal panel can be reduced, and thus it can effectively prevent electrostatic charges from gathering on the aforesaid surfaces, thereby preventing the substrate of the liquid crystal panel from being damaged by the electrostatic charges and ensuring product percent of pass.

To make above content of the present invention more easily understood, it will be described in details by using preferred embodiments in conjunction with the appending drawings.

### BRIEF DESCRIPTION OF THE DRAWINGS

FIGS. 1a to 1c are schematic diagrams showing a cassette utilized for transporting a substrate of a liquid crystal panel in conventional skills. FIG. 1d is a side view of FIG. 1c.

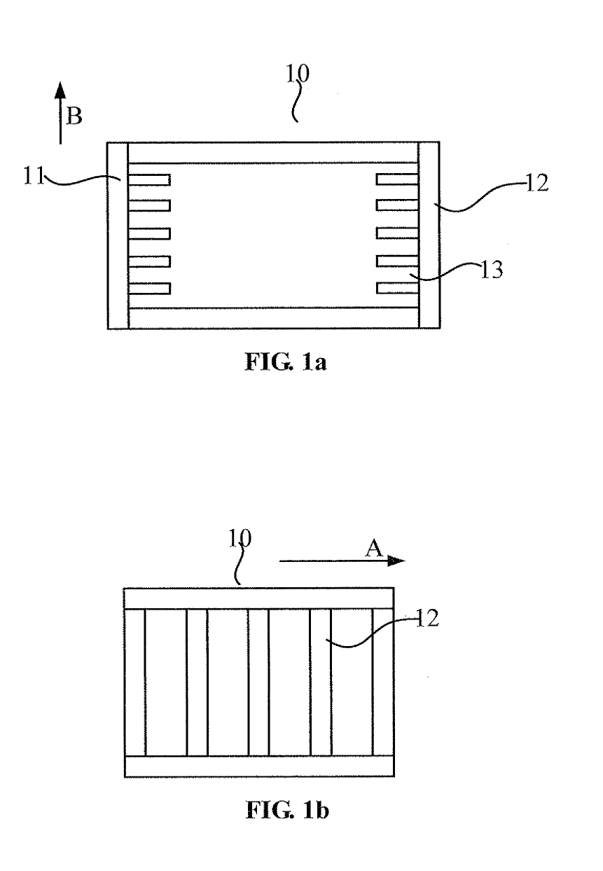

FIG. 2 is a schematic structural diagram showing a system provided for controlling transportation of a substrate of a liquid crystal panel according to the present invention.

FIG. 3 is a schematic structural diagram showing a humidifying apparatus of the present invention.

FIG. 4 is a flow chart of a method for controlling transportation of a substrate of a liquid crystal panel according to the present invention.

### DETAILED DESCRIPTION OF THE INVENTION

The following descriptions for the respective embodiments are specific embodiments capable of being implemented for illustrations of the present invention with referring to appended figures.

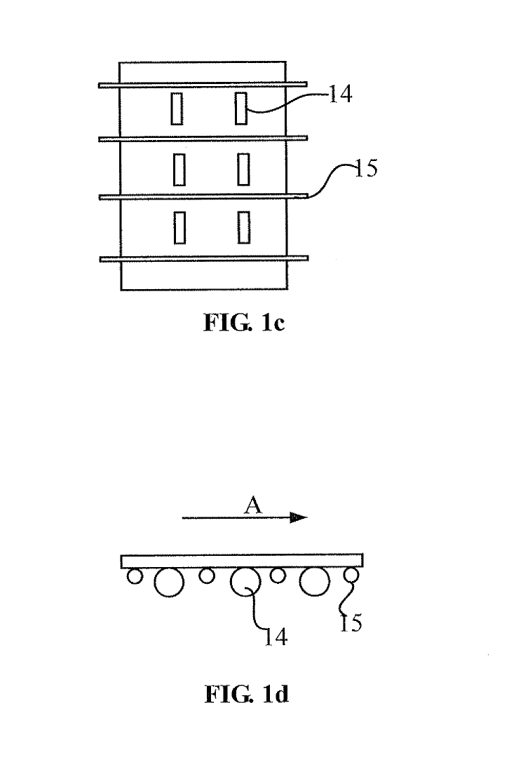

FIG. 2 is a schematic structural diagram showing a system provided for controlling transportation of a substrate of a liquid crystal panel according to the present invention. The system provided for controlling transportation of the substrate of the liquid crystal panel comprises a transport apparatus 21 and a humidifying apparatus 22.

The substrate of the liquid crystal panel required to be transported is placed into the transport apparatus 21. That is, the transport apparatus 21 is utilized to transport the substrate of the liquid crystal panel. The humidifying apparatus 22 is disposed at at least one side of the transport apparatus 21. The humidifying apparatus 22 is utilized to humidify the transport apparatus 21 so as to form a mist in the transport apparatus 21. For example, the substrate of the liquid crystal panel is a piece of thin-film-transistor (TFT) glass.

The transport apparatus 21 comprises a left column 211 and a right column 212. The transport apparatus 21 also has a slot 213 disposed therein. The slot 213 of the transport apparatus 21 has a wheel or a roller 214 disposed at the bottom thereof. The transport apparatus 21 further comprises a supporting rope 215 disposed therein. The supporting rope 215 penetrates into the wheel 214. In the present invention, the substrate of the liquid crystal panel is not only supported and fixed by the slot 213, but also supported by the supporting rope 215.

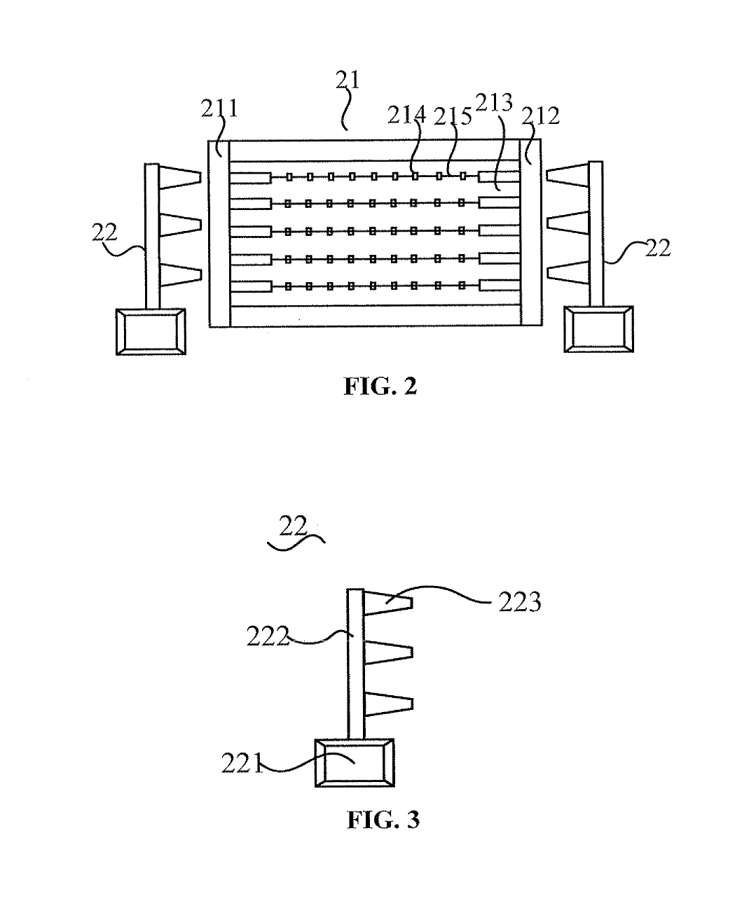

In one preferred embodiment of the present invention, the humidifying apparatus 22 is a mist generator. The humidifying apparatus 22 certainly can be made in other forms, which will not be detailed here. Referring to FIG. 3, FIG. 3 is a schematic structural diagram showing the humidifying apparatus 22 of the present invention.

The humidifying apparatus 22 comprises a mist generating cavity 221, a pipe 222, and a nozzle 223. The mist generating cavity 221 is utilized to hold the water (e.g., pure water). The pipe 222 is used for carrying the water. The water will enter into the nozzle 222 via the pipe 222 under pressure. Then, the nozzle 223 generates atomized pure water for spraying into the transport apparatus 21.

In concrete implementation, the humidifying apparatus 22 sprays the atomized pure water into the transport apparatus 21 so as to form a mist in the transport apparatus 21. As long as the mist can be formed in the transport apparatus 21, it also can spray liquid water of other forms, which will not be detailed here. Meanwhile, after forming the mist, particles of the atomized pure water may range from one to five micrometers in diameter.

Specifically, the humidifying apparatus 22 will be controlled to spray toward a region where the substrate of the liquid crystal panel is in contact with the transport apparatus 21, for example, spraying toward the inner sides of the slot 213 or spraying toward the wheel 214 such that a better result for removing static electricity can be obtained.

Meanwhile, after spraying with the humidifying apparatus 22, the relative humidity in the transport apparatus 21 is greater than 65%. Preferably, the relative humidity is 65%-70%.

The working principles for the system provided for controlling transportation of the substrate of the liquid crystal panel as shown in FIG. 2 are described below.

During transporting the substrate of the liquid crystal panel, the substrate of the liquid crystal panel is firstly placed at an entrance of the slot 213 of the transport apparatus 21, and the substrate of the liquid crystal panel is inserted into the slot 213 with the help of the wheel 214.

After that, the transport apparatus 21 is humidified by utilizing the humidifying apparatus 22. Specifically, the humidifying apparatus 22 is controlled to spray atomized pure water toward the inner sides of the slot 213 and the wheel 214 of the transport apparatus 21 so as to form a mist in the transport apparatus 21. The mist or the atomized pure water is formed by particles that range from one to five micrometers in diameter. The mist makes the relative humidity in the transport apparatus 21 range from 65% to 70%.

Since the relative humidity in the transport apparatus 21 range from 65% to 70%, the mist will form a water film in the transport apparatus 21. The water film is a layer that is extremely thin. For example, the water film is formed on the surfaces of the wheel 214 and the substrate of the liquid crystal panel and the inner surface of the slot 213. The water film can dissolve carbon dioxide (CO2) in air inside the transport apparatus 21 such that the resistance measured on the aforesaid surfaces can be reduced, and thus it can prevent electrostatic charges from gathering on the aforesaid surfaces, thereby preventing the substrate of the liquid crystal panel from being damaged by the electrostatic charges and ensuring product percent of pass.

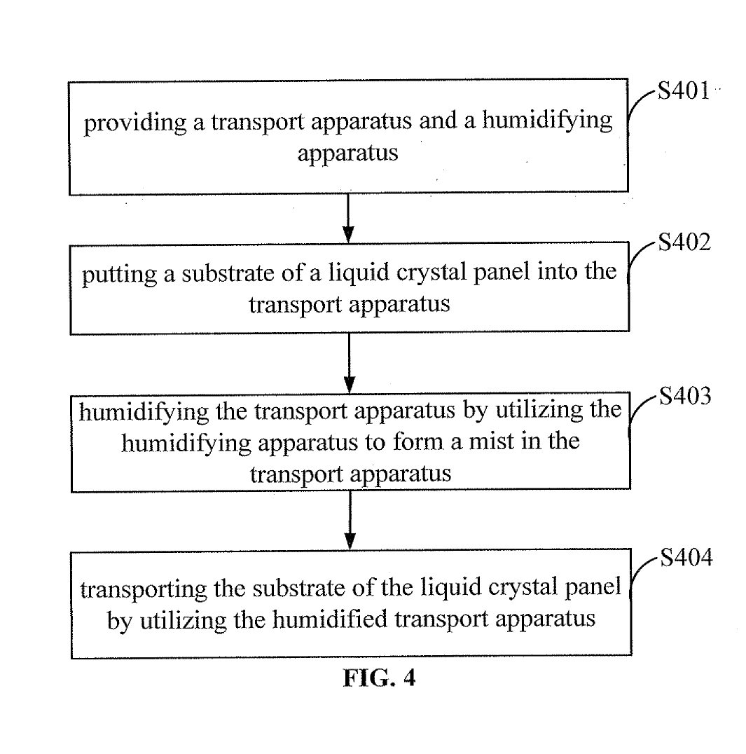

FIG. 4 is a flow chart of a method for controlling transportation of a substrate of a liquid crystal panel according to the present invention.

In Step S401, a transport apparatus 21 and a humidifying apparatus 22 are provided.

In Step S402, the substrate of the liquid crystal panel is put into the transport apparatus 21.

In Step S403, the transport apparatus 21 having the substrate of the liquid crystal panel placed thereinto is humidified by utilizing the humidifying apparatus 22 so as to form a mist in the transport apparatus 21.

In concrete implementation, the humidifying apparatus 22 is controlled to spray atomized pure water toward a region where the substrate of the liquid crystal panel is in contact with the transport apparatus 21 so as to form the mist in the transport apparatus 21, for example, spraying toward the inner sides of the slot 213 or spraying toward the wheel 214 such that a better result for removing static electricity can be obtained.

In the spraying process, a spray amount of the humidifying apparatus 22 is controlled so as to make the relative humidity in the transport apparatus 21 range from 65% to 70%. The mist or the atomized pure water is formed by particles that range from one to five micrometers in diameter.

In the present invention, the humidifying apparatus 22 is a mist generator, preferably. It also can be implemented by other humidifying apparatuses, which will not be detailed here.

In Step S404, the substrate of the liquid crystal panel is transported by utilizing the humidified transport apparatus 21.

The present invention is to humidify the transport apparatus 21 by utilizing the humidifying apparatus 22 to form a mist in the transport apparatus 21. The mist will form a water film on the surfaces of the transport apparatus 21 and the substrates of the liquid crystal panel. The water film is a layer that is extremely thin. The water film can dissolve carbon dioxide in air such that the resistance measured on the surfaces of the transport apparatus 21 and the substrate of the liquid crystal panel can be reduced, and thus it can effectively prevent electrostatic charges from gathering on the aforesaid surfaces, thereby preventing the substrate of the liquid crystal panel from being damaged by the electrostatic charges.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A method for controlling transportation of a substrate of a liquid crystal panel, said method comprising steps of:
providing a transport apparatus and a humidifying apparatus;
putting the substrate of the liquid crystal panel into the transport apparatus;
spraying atomized pure water into the transport apparatus by utilizing the humidifying apparatus to form a mist in the transport apparatus, and meanwhile controlling a spray amount of the humidifying apparatus to make relative humidity in the transport apparatus greater than 65%, wherein particles of the atomized pure water range from one to five micrometers in diameter; and
transporting the substrate of the liquid crystal panel by utilizing the humidified transport apparatus.

2. The method according to claim 1, wherein the humidifying apparatus is a mist generator.

3. The method according to claim 1, wherein when forming the mist in the transport apparatus by spraying the atomized pure water into the transport apparatus by utilizing the humidifying apparatus, the humidifying apparatus is controlled to spray toward a region where the substrate of the liquid crystal panel is in contact with the transport apparatus.

4. A method for controlling transportation of a substrate of a liquid crystal panel, said method comprising steps of
providing a transport apparatus and a humidifying apparatus;
putting the substrate of the liquid crystal panel into the transport apparatus;
humidifying the transport apparatus having the substrate of the liquid crystal panel placed thereinto by utilizing the humidifying apparatus to form a mist in the transport apparatus; and
transporting the substrate of the liquid crystal panel by utilizing the humidified transport apparatus.

5. The method according to claim 4, wherein the humidifying apparatus is a mist generator.

6. The method according to claim 4, wherein the step of humidifying the transport apparatus having the substrate of the liquid crystal panel placed thereinto by utilizing the humidifying apparatus to form the mist in the transport apparatus comprises:
spraying atomized pure water into the transport apparatus by utilizing the humidifying apparatus;
wherein particles of the atomized pure water range from one to five micrometers in diameter.

7. The method according to claim 4, wherein when forming the mist in the transport apparatus by spraying the atomized pure water into the transport apparatus by utilizing the humidifying apparatus, the humidifying apparatus is controlled to spray toward a region where the substrate of the liquid crystal panel is in contact with the transport apparatus.

8. The method according to claim 4, wherein when forming the mist in the transport apparatus by spraying the atomized pure water into the transport apparatus by utilizing the humidifying apparatus, a spray amount of the humidifying apparatus is controlled so as to make relative humidity in the transport apparatus greater than 65%.

9. A system provided for controlling transportation of a substrate of a liquid crystal panel, said system comprising a transport apparatus and a humidifying apparatus;
wherein said transport apparatus is utilized to accommodate the substrate of the liquid crystal panel as well as transport the substrate of the liquid crystal panel;
wherein said humidifying apparatus is disposed at at least one side of the transport apparatus, and said humidifying apparatus is utilized to humidify the transport apparatus to form a mist in the transport apparatus.

10. The system according to claim 9, wherein the humidifying apparatus is a mist generator.

11. The system according to claim 9, wherein the mist formed in the transport apparatus is atomized pure water, and wherein particles of the atomized pure water range from one to five micrometers in diameter.

12. The system according to claim 9, wherein the humidifying apparatus is also utilized to be controlled to spray toward a region where the substrate of the liquid crystal panel is in contact with the transport apparatus.

13. The system according to claim 9, wherein relative humidity in the transport apparatus is greater than 65% after spraying by utilizing the humidifying apparatus.
